(19) United States
(12) Patent Application Publication
(10) Pub. No.: US 2006/0151780 A1
(43) Pub. Date: Jul. 13, 2006

(54) Hybrid silicon-molecular memory cell with high storage density

(76) Inventor: Klaus-Dieter Ufert, Unterschleissheim (DE)

Correspondence Address: EDELL, SHAPIRO & FINNAN, LLC, 1901 RESEARCH BOULEVARD, SUITE 400, ROCKVILLE, MD, 20850, US

(21) Appl. No.: 11/289,784

(22) Filed: Nov. 30, 2005

(30) Foreign Application Priority Data
Nov. 30, 2004 (DE) 10 2004 057 790.0

(51) Int. Cl. H01L 29/08; H01L 21/8242

(52) U.S. Cl. 257/40; 257/306; 438/244; 257/E51.041

(57) ABSTRACT

A nonvolatile memory cell including a substrate, a first electrode and a second electrode, and an active layer between the first and second electrodes. The active layer includes a self-assembled monolayer of an organic compound, and the second electrode is constructed from carbon-containing materials.

### CROSS REFERENCE TO RELATED APPLICATIONS

This application claims priority under 35 USC §119 to German Application No. DE 10 2004 057 790.0, filed on Nov. 30, 2004, and titled “Hybrid Silicon-Molecular Memory Cell with Storage Density,” the entire contents of which are hereby incorporated by reference.

### FIELD OF THE INVENTION

The invention relates to a memory cell including a layer of a self-assembled monolayer.

### BACKGROUND

One of the essential endeavors in the further development of modern memory technologies is to increase the integration density, and so great importance is accorded to reducing the feature sizes of the memory cells on which the memory devices are based.

A number of concepts have been proposed for memory arrays or memory cells which are intended to reduce the size of the memory cells. Main memories with extremely short access times such as are employed nowadays to a huge extent in computers are almost exclusively manufactured on the basis of volatile memory architectures (“volatile memory”), in particular in DRAM technology (“Dynamic Random Access Memory”). DRAM technology is based on storing electronic charges in a capacitive memory element, that is to say in a capacitor. Each memory cell represents a memory unit (“bit”) and is formed by a capacitor and a selection transistor, such as e.g. a field effect transistor (FET). The selection transistor has the task of electrically insulating the individual memory cells from one another and from the periphery of the cell array. The switching of the respective selection transistor then enables any arbitrary cell to be accessed individually and in a targeted manner (“random access”). The DRAM architecture is distinguished by an extremely small space requirement which may be less than 1 μm per memory cell, and extremely low manufacturing costs, so that approximately 10⁸ memory cells can be fabricated for less than ε1. A crucial disadvantage of the DRAM concept, however, is the volatility of the stored information, since the charge stored in the capacitor is so small and is generally less than 500,000 electrons, so that, when the supply voltage is switched off, it is lost after a short time (within a few milliseconds) on account of leakage currents within the cell array.

Another concept relates to nonvolatile memories, which do not lose the stored information, even after the supply voltage has been switched off, over long periods of time of possibly several years. These nonvolatile memories are of interest for a broad spectrum of applications, such as e.g. digital cameras, mobile telephones, mobile navigation instruments, computer games, etc., and could also revolutionize the manner of dealing with computers, since a start-up of the computer after being switched on would be unnecessary (“instant-on computer”). The nonvolatile memory technologies that already exist include so-called flash memories, in which the information is stored in the form of electronic charge in the gate dielectric of a silicon field effect transistor and is detected as a change in the threshold voltage of the transistor. Since the electronic charge is “trapped” in the gate dielectric of the transistor, it is not lost when the supply voltage is switched off. An essential disadvantage of flash technology, however, is the relatively high write and erase voltages resulting from the need to inject the electronic charge to be stored into the gate dielectric reliably and reproducibly and to remove it from there again. A further disadvantage is the significantly longer access times in comparison with DRAM technology, and also the restricted reliability on account of the high loading of the gate dielectric during writing and erasing.

Therefore, there is a need to develop new technologies for nonvolatile semiconductor memories based on diverse physical concepts. These include ferroelectric and magnetoresistive memories, in which the stored information is read out as a change in the electrical polarization on account of the displacement of the central atom in a perovskite crystal and, respectively, as a change in an electrical resistance in an arrangement of ferromagnetic layers.

The abovementioned memory concepts are produced and developed exclusively on silicon platforms, so that exclusively monocrystalline silicon substrates have to be accessed during the fabrication of the memory elements. The transistors assigned to the memory cells are likewise fabricated on the silicon platform.

As an alternative to the memory technologies mentioned above, diverse molecular memory concepts have been discussed for a few years. The principle of action of a molecular memory is the targeted, reversible, stable (nonvolatile) and detectable change in a specific electrical or optical property of an organic molecule or an order of organic molecules. This change in molecular properties permits the targeted storage of information at the corresponding electroactive molecules. A particular feature of molecular memories is the potentially relatively small quantity of molecules which are required for realizing a memory element.

Therefore, the fabrication of molecular self-assembled monolayers (SAM) is being discussed as an alternative to the single molecule approach. Molecular self-assembly is the production of molecular monolayers through spontaneous orientation and direct adsorption of organic molecules at solid surfaces. Molecular self-assembly may optionally be effected from the gas phase, from liquid solutions, or by targeted transfer from a flexible stamp, and ideally leads to the formation of dense organic monolayers having a high degree of ordering and with high chemical resistance and mechanical robustness. Molecular self-assembly is based on the chemical binding of long-chain hydrocarbons with reactive anchor groups on smooth substrate surfaces, which undergo an interaction with the reactive anchor groups, which enables a sufficiently high density of suitable binding positions.

The SAM systems that have been investigated best include molecular systems with thiol anchor groups, which enable self-assembly on noble metals, such as e.g. gold, and also on specific compound semiconductors, such as e.g. gallium arsenide and indium phosphide, and silanes, which enable self-assembly on natively oxidized silicon.

There are a multiplicity of organic compounds which bind, by means of the anchor groups described above, to the surfaces of different materials to form the self-assembled monolayer. One class of organic molecules is organometallic compounds such as e.g. metalloporphyrins and ferrocenes. The preparation and the properties of these classes of compounds are described in Gryko et al., J. Org. Chem. 2000, 66, 7345-7355. This publication showed that porphyrin molecules which are complexed with a metal and have an anchor group can form a self-assembled monolayer between two electrodes which, depending on the redox state of the porphyrin molecules, has three different stable states having different electrical resistances. The porphyrin and ferrocene molecules can therefore be used as an active layer in a nonvolatile memory cell.

For realizing molecular memory cells based on self-assembled monolayers, the molecular monolayer has to be arranged between two electrically conductive electrodes in such a way that each of the two electrodes respectively makes contact with an end of the molecules. The second electrode according to the invention is also called top electrode or top contact layer.

While contact is made between the molecular memory layer and the substrate by a specially selected anchor group which is directly chemically bonded to the memory molecule, an electrolytic, gel-like intermediate layer is used with respect to the metallic top contact. This ionically conductive intermediate layer is chemically very complex, difficult to encapsulate on account of the gel-like consistency and currently limits the speed of charge carrier transport in the capacitive memory element (in this respect, see Q. Li et al., Appl. Phys. Lett. Vol. 83(1) 2003, p. 198). The existing problem of the intermediate layer with respect to the metallic contact has hitherto been able to be solved only in an unsatisfactory manner by a perfluorosulfonate or a perfluorinated ionomer (also known as Nafion®) (in this respect, see U.S. Pat. No. 6,381,169 and U.S. Pat. No. 6,212,993). The essential disadvantages of this intermediate layer with regard to the function of the memory element are first of all the inadequate mechanical strength caused by the gel-like mechanical consistency of the molecular complex, and the difficulty in encapsulating the hybrid silicon-molecular memory element at the customary CMOS process temperatures. The low mobility of the ions in the gel-like layer, moreover, limits the speed of the charge carriers of the memory element and hence the cycle time. The chemical complexity and the sensitivity of the organic molecular compounds toward higher temperatures and UV radiation likewise limit the selection of the methods for depositing the metallic top contact. Furthermore, deposition methods in which the substrate or the layer onto which deposition is effected experiences directly or indirectly charging by electrons outdiffusing from the plasma cause an inhomogeneous distribution of the ions in the Nafion® molecular complex, which may lead to irreparable damage to the molecular structure.

To summarize, the use of a Nafion® intermediate layer is not only not compatible with the CMOS process steps but further cannot satisfy the memory-relevant requirements.

### SUMMARY

An object of the present invention is to provide a hybrid silicon memory cell that includes a self-assembled monolayer of an organometallic compound.

It is another object of the present invention to provide a memory cell that is compatible with CMOS processes and enables faster cycle times than the memory cell in accordance with the prior art.

A further object of the invention is to provide a method for fabricating a nonvolatile memory cell on the basis of porphyrin or ferrocene derivatives, the method being compatible with CMOS processes and enabling memory cells having faster cycle times.

The aforesaid objects are achieved individually and/or in combination, and it is not intended that the present invention be construed as requiring two or more of the objects to be combined unless expressly required by the claims attached hereto.

In accordance with the present invention, a memory cell comprises a substrate, a first electrode and a second electrode, and an active layer between the first and second electrodes. The active layer includes a self-assembled monolayer of an organic compound. The second electrode is constructed from carbon-containing materials, and the organic compound has one of the general formulas I and II: 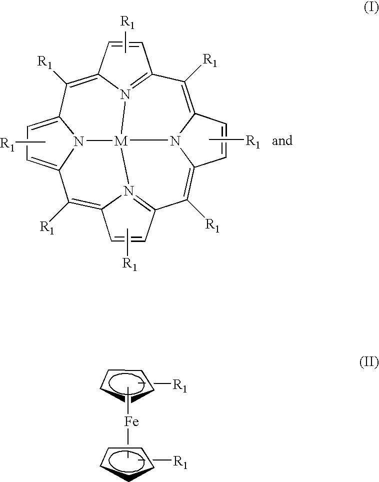
where R₁, independently of one another, is hydrogen, an alkyl chain having 1-20 carbon atoms, an aromatic group with an alkyl chain having 1-4 carbon atoms which can be substituted by one or more functional groups, under the precondition that at least one of the R₁ groups in the general formula I or II contains a radical selected from the group consisting of —PO₃H, —SH, —OH, —NH₂, —NHR, —NR₂, —PHR, —PR₂, —COOH, —CONH₂, —CONHOH and —CONHNH₂, and M is a metal selected from the group consisting of Zn, Cu, Co, Ag and Eu. A carbon-containing layer is arranged on the self-assembled monolayer of the organic compound.

In further accordance with the present invention, a method of forming a memory cell comprises providing a substrate, depositing and, if necessary, patterning a first electrode, bringing the first electrode into contact with an organic compound, as a result of which a self-assembled monolayer of the organic compound is formed, and depositing a carbon-containing layer onto the self-assembled monolayer of the organic compound. The organic compound has one of the general formulas I and II 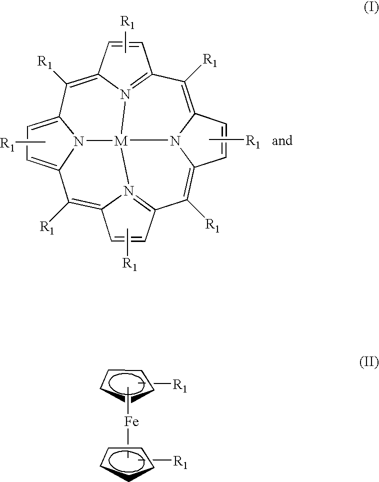
where R₁, independently of one another, is hydrogen, an alkyl chain having 1-20 carbon atoms, an aromatic group with an alkyl chain having 1-4 carbon atoms which can be substituted by one or more functional groups, under the precondition that at least one of the R₁ groups in the general formula I or II contains a radical selected from the group consisting of —PO₃H, —SH, —OH, —NH₂, —NHR, —NR₂, —PHR, —PR₂, —COOH, —CONH₂, —CONHOH and —CONHNH₂, and M is a metal selected from the group consisting of Zn, Cu, Co, Ag and Eu.

The intermediate layer between the self-assembled monolayer of the organic compound and the top contact comprises a carbon or hydrocarbon layer, which may also be doped with a metallic component in order to improve the electrical conductivity. The essential advantage of the layer according to the invention is that the conductivity in the carbon layers is based on electron transport and, therefore, does not have a limiting effect for the cycle time or access time of the memory element. Moreover, the conductivity of this layer can be varied within wide limits from having very good conductivity (10³ Scm⁻¹) to insulating.

The mechanical strength of the carbon or hydrocarbon layer may likewise be varied within wide limits from graphite-like through to the very hard diamond-like carbon. It is likewise possible to set both the conductivity and the mechanical strength in gradient-like fashion within the layer or from bottom to top in the direction of the normal to the layer. In this case, metallic dopings enable a situation in which a hard mechanically solid layer can also have a good electronic conductivity and, ultimately, the metallic top contact can also be realized thereby.

The carbon layers are extremely thermostable, very simple with regard to the chemical structure and can be encapsulated absolutely compatibly with CMOS processes. The hydrocarbon atoms can be chemically coupled to the porphyrin or ferrocene memory molecules without any problems and likewise enter into a good electrical connection with the metallic top contact if the latter is still required.

In principle, the mechanically solid, doped hydrocarbon layer having good conductivity may also fulfill the function of the top contact, whereby the additional top contact can be obviated. In this case, this layer may have a gradient in the mechanical consistency in the direction of the normal to the layer, beginning with graphite, polymer-like to sufficiently hard and solid. This can be achieved in one process step through variations of the process parameters and of the reactive gas.

With the integration of the new gradient-like carbon layer, it is possible to improve the function of the hybrid silicon-molecular memory element with regard to cycle time, access time and stability and, in principle, to obviate an additional top contact.

The above and still further objects, features and advantages of the present invention will become apparent upon consideration of the following detailed description of specific embodiments thereof, particularly when taken in conjunction with the accompanying drawing.

### BRIEF DESCRIPTION OF THE DRAWINGS

FIG. 1 depicts a schematic cross section through a hybrid silicon-molecular memory cell based on a self-assembled monolayer.

### DETAILED DESCRIPTION

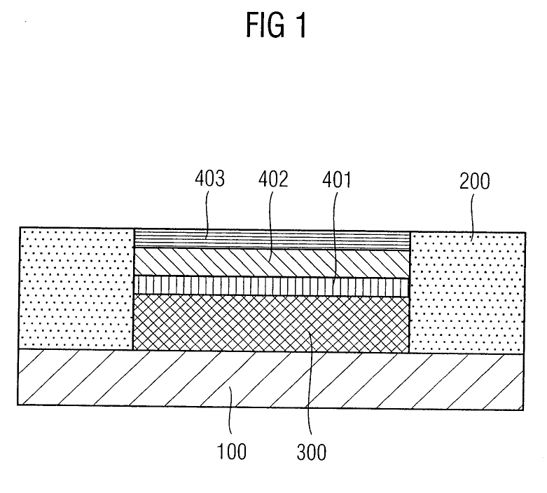

The structure described in FIG. 1 corresponds to a memory cell according to the invention. A first electrode (200) is deposited on a substrate and patterned, the substrate being a flexible substrate (100) made of, e.g., a polymer film. In this case, the first electrode (200) includes a material on which the suitable porphyrin derivatives form a self-assembled monolayer. If, e.g., the porphyrin molecule has thiol groups, the first electrode (200) includes a metal selected from the group consisting of Au, Ag, Pt or Pd. If the porphyrin molecule has silane or phosphonic acid groups, the first electrode (200) includes silicon/silicon oxide layers. The methods for producing self-assembled monolayers are known to the person skilled in the art and described, e.g., in S. Gowda, G. Mathur, Q. Li, Q. Zhao, J. S. Lindsey, K. Mobley, D. F. Bocian, V. Misra, IEDM Conf., Washington D.C. (December 2003) p. 2211 or D. T. Gryko, C. Clausem, J. S. Lindsey, J. Org. Chem. Vol. 64, (1999), p. 8635.

The self-assembled monolayer which has formed on the first electrode represents the active layer (300).

According to the invention, a layer made of a carbon-containing material is constructed on the active layer (300). As shown in FIG. 1, the layer according to the invention may include a plurality of layers (401; 402; 403), the layer (401) directly connected to the organic molecule being a relatively soft, weakly doped carbon layer, the subsequent layer (402) being a solid carbon layer doped with a metal, and the succeeding layer (403) being a solid metal-carbon layer, which is heavily doped and serves as the top contact.

The layer according to the invention may be deposited by DC sputtering, for example. For this purpose, a metallic target, for example silver, is used, and use is made of a gas mixture of methane, hydrogen and argon at a total pressure of approximately 5×10⁻³ mbar. In order to obtain a gradient in the mechanical consistency, a low sputtering power is used at the beginning, and this yields a softer carbon layer (401) having good conductivity, which, as the DC sputtering power increases, undergoes transition via a more solid silver-doped carbon layer (402) to a sufficiently solid Ag-carbon layer (403) having good conductivity. Ultimately, it is possible to obtain a silver layer at the surface by reducing the proportion of methane and hydrogen in the mixed gas. The hardness of the carbon/silver-carbon layer can additionally be controlled by a negative bias voltage which is applied to the substrate support.

Deposition of the doped carbon layer by co-sputtering of a graphite and metal target can likewise be used in order to obtain layers having good conductivity with a solidity/hardness gradient in the direction of the normal to the layer.

In principle, the doped carbon layers can also be deposited by plasma-enhanced chemical vapor deposition (PECVD) in a commercially available reactor. For this purpose, the plasma may be excited with the traditional excitation frequencies of 13.56 MHz, 27.12 MHz and also by microwaves. The working gas used may typically be methane, ethene or CₓH_{y}, diluted in neon or some other noble gas, at a pressure of, for example, approximately 1 Pa to approximately 100 Pa in the reactor. Since the carbon or doped hydrocarbon layer to be deposited does not have to have extremely high hardness, but rather only has to be conductive and sufficiently solid, it is possible to dispense with applying an additional bias voltage to the electrode on which the substrate is positioned. Doping with metal-containing precursor compounds in order to obtain a metal-hydrocarbon layer can be effected by admixture to the reactive gas.

If it is necessary to protect the ferrocene- or porphyrin-molecular monolayers from the UV radiation of the plasma, it is possible to choose the distance between the substrate and the sputtering target to be large, or, in the case of PECVD, to use a modified embodiment, so-called remote PECVD, in which the plasma is generated at a greater distance from the substrate.

The memory cell according to the invention can be integrated e.g. in a cross-point array.

For this purpose, the bottom electrode is deposited on a substrate made, e.g., of plastic by the thermal vapor deposition of silicon, aluminum, titanium, gold, silver, platinum or palladium and is patterned. A self-assembled monolayer of a metalloporphyrin or ferrocene derivative is then produced thereon.

The carbon-containing layer is fabricated on the self-assembled monolayer in the manner described above.

According to the invention, however, the porphyrin or ferrocene compound may be filled into a hole that has been opened above the first electrode (via concept). The principles of both of these concepts, namely the cross-point concept and the via concept, are known to the person skilled in the art and they can both be employed in the present application.

While the invention has been described in detail and with reference to specific embodiments thereof, it will be apparent to one skilled in the art that various changes and modifications can be made therein without departing from the spirit and scope thereof. Accordingly, it is intended that the present invention covers the modifications and variations of this invention provided they come within the scope of the appended claims and their equivalents.

### LIST OF REFERENCE SYMBOLS

100 Flexible substrate
200 First electrode
300 Active layer
401 Soft, weakly doped carbon layer
402 Solid carbon layer doped with a metal
403 Solid, heavily doped metal-carbon layer

What is claimed is:

1. A nonvolatile memory cell comprising:
a substrate;
a first electrode and a second electrode; and
an active layer disposed between the first and second electrodes, the active layer comprising a self-assembled monolayer of an organic compound having one of the general formulas I and II: 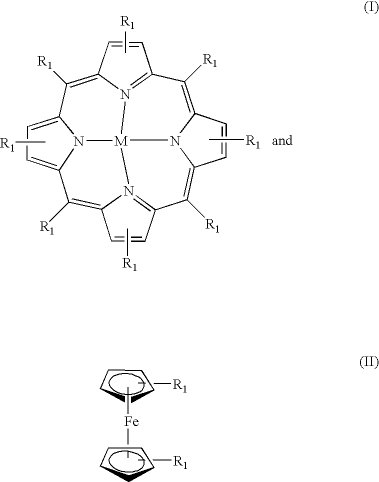
where each R₁ is independent of the other and is one of hydrogen, an alkyl chain having 1-20 carbon atoms, and an aromatic group with an alkyl chain having 1-4 carbon atoms that is substituted by one or more functional groups, wherein at least one of the R₁ groups in the general formula I or II includes a radical selected from the group consisting of —PO₃H, —SH, —OH, —NH₂, —NHR, —NR₂, —PHR, —PR₂, —COOH, —CONH₂, —CONHOH and —CONHNH₂, and M is a metal selected from the group consisting of Zn, Cu, Co, Ag and Eu; and
a carbon-containing layer arranged on the self-assembled monolayer of the organic compound.

2. The memory cell of claim 1, wherein the second electrode comprises a plurality of layers.

3. The memory cell of claim 1, wherein the substrate comprises a polymer.

4. The memory cell of claim 1, wherein the first electrode comprises at least one of polysilicon, Si, SiO₂ and Au.

5. The memory cell of claim 1, wherein the memory cell is arranged in a memory cell array and the memory cell array is formed as a cross-point array.

6. The memory cell of claim 1, wherein the memory cell is arranged in a memory cell array and the cell is arranged in a contact hole between the first and second electrodes.

7. The memory cell of claim 1, wherein the second electrode is deposited by an MOCVD method.

8. The memory cell of claim 7, wherein the MOCVD method is carried out at a pressure of approximately 0.5 mbar.

9. The memory cell of claim 7, wherein the MOCVD method is carried out at a temperature of approximately 180° C.

10. A method for fabricating a nonvolatile memory cell, comprising:
providing a substrate;
depositing and/or patterning a first electrode;
bringing the first electrode into contact with an organic compound, resulting in a self-assembled monolayer of the organic compound being formed, wherein the organic compound has one of the general formulas I and II: 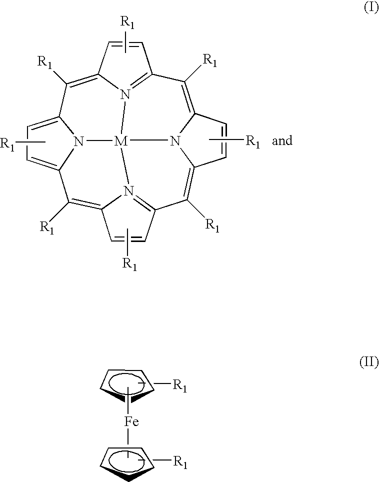
where each R₁ is independent of the other and is one of hydrogen, an alkyl chain having 1-20 carbon atoms, and an aromatic group with an alkyl chain having 1-4 carbon atoms that is substituted by one or more functional groups, wherein at least one of the R₁ groups in the general formula I or II includes a radical selected from the group consisting of —PO₃H, —SH, —OH, —NH₂, —NHR, —NR₂, —PHR, —PR₂, —COOH, —CONH₂, —CONHOH and —CONHNH₂, and M is a metal selected from the group consisting of Zn, Cu, Co, Ag and Eu; and
depositing a carbon-containing layer onto the self-assembled monolayer of the organic compound.

11. A nonvolatile memory cell containing:
a substrate;
a first electrode comprising a material selected from the group consisting of polysilicon, Au, Ag, Pt, Pd, and Si;
an active layer comprising one of a metalloporphyrin and a ferrocene derivative, the active layer being formed between the first and second electrodes as a self-assembled monolayer; and
a second electrode comprising at least one carbon-containing layer.
